(19) United States
(12) Patent Application Publication
(10) Pub. No.: US 2006/0145323 A1
(43) Pub. Date: Jul. 6, 2006

(54) Multi-chip package mounted memory card

(76) Inventor: Chang-hwan Lee, Gyeonggi-do (KR)

Correspondence Address: MYERS BIGEL SIBLEY & SAJOVEC, PO BOX 37428, RALEIGH, NC, 27627, US

(21) Appl. No.: 11/297,276

(22) Filed: Dec. 8, 2005

(30) Foreign Application Priority Data
Jan. 5, 2005 (KR) 10-2005-0000809

(51) Int. Cl. H01L 23/02

(52) U.S. Cl. 257/679

(57) ABSTRACT

A multi-chip package mounted memory card includes at least one multi-chip package mounted on a printed circuit board, and card connectors connected to electrode terminals on the multi-chip package via a wiring on the printed circuit board. The same or different types of multi-chip packages may be mounted on the memory card, and same or different types of semiconductor chips may be mounted on each multi-chip package. In the multi-chip package, input pins or output pins may be connected to the semiconductor chips such that they are shared by the semiconductor chips, or may be separately connected to the semiconductor chips. Also, the semiconductor chips in the multi-chip package may have separate power supply lines or may share a power supply line.

### RELATED APPLICATION

This application claims the priority of Korean Patent Application No. 10-2005-0000809, filed on Jan. 5, 2005, in the Korean Intellectual Property Office, the disclosure of which is incorporated herein in its entirety by reference.

### FIELD OF THE INVENTION

The present invention relates to a semiconductor memory device, and more particularly, to a multi-chip package mounted memory card.

### BACKGROUND

A mobile appliance, such as a mobile phone, a personal digital assistant (PDA), or a hand-held multimedia appliance, uses a multi-chip package (MCP) as a memory solution. The MCP is a compact device that operates at high speed, which is fabricated by mounting a plurality of semiconductor chips at a high density into a package. The MCP can be a desirable memory solution for a compact, high-performance mobile appliance. As mobile appliances have been developed to have higher performance and more functions, the capacity of memory devices used therein may also need to be increased.

The MCP is mounted on a printed circuit board (PCB) of the mobile appliance using soldering. However, the memory capacity of a MPC soldered to the PCB is limited. For instance, when a 10M-byte RAM and a 60M-byte ROM are installed into a phone with 10-second video recording capability, it is impossible to store a plurality of 20-second continuous videos in the phone. Further, there is a limit to upgrading the functions of the mobile appliance.

One approach to these problems is to mount the MCP soldered to the PCB onto a memory card which can be attached to and detached from a memory card. Accordingly, there is a growing need to develop an MCP-mounted memory card.

### SUMMARY

The present invention provides a multi-chip package (MCP) mounted memory card.

According to one aspect of the present invention, embodiments of the invention are directed to a memory card including at least one multi-chip package mounted on a printed circuit board, and card connectors electrically connected to electrode terminals on the multi-chip package via a conductive trace on the printed circuit board. The same or different types of multi-chip packages may be mounted on the memory card, and the same or different types of semiconductor chips may be mounted on each multi-chip package. In the multi-chip package, input pins or output pins may be connected to the semiconductor chips such that they are shared by the semiconductor chips, or be separately connected to the semiconductor chips. Also, the semiconductor chips in the multi-chip package may have separate power supply lines or share a power supply line.

According to a second aspect of the invention, embodiments of the invention are directed to a memory card, comprising: a printed circuit board; at least one multi-chip package mounted to the printed circuit board; and card connectors mounted on the printed circuit board. The multi-chip package includes a plurality of memory chips arranged in a vertically stacked relationship above a package board. The card connectors are electrically connected to electrode terminals of the package board of the multi-chip package.

According to a third aspect of the invention, embodiments of the invention are directed to a memory card, comprising: a printed circuit board; and at least one multi-chip package mounted to the printed circuit board. The multi-chip package includes a plurality of memory chips arranged in a vertically stacked relationship above a package board. The plurality of memory chips comprises different kinds of memory chips.

Use of an MCP-mounted memory card according to at least some aspects of the present invention an facilitate the increase of the memory capacity of a mobile appliance. Also, it may be possible to increase the compatibility of the memory card by stacking different types of semiconductor chips on the MCP.

### BRIEF DESCRIPTION OF THE DRAWINGS

The above and other aspects and advantages of the present invention will become more apparent by describing in detail exemplary embodiments thereof with reference to the attached drawings in which:

FIG. 1 is a view of a memory card according to an embodiment of the present invention;

FIG. 2 is a cross-sectional view of a multi-chip package (MCP) mounted on the memory card illustrated in FIG. 1, according to another embodiment of the present invention;

FIG. 3 is a block diagram of a communication and multimedia device which is a mobile device with memory cards such as that illustrated in FIG. 1, according to an embodiment of the present invention;

FIG. 4 is a cross-sectional view of a memory card connected to the communication and multimedia device illustrated in FIG. 3, according to an embodiment of the present invention; and

FIG. 5 is a cross-sectional view of a memory card connected to the communication and multimedia device illustrated in FIG. 3, according to another embodiment of the present invention.

### DETAILED DESCRIPTION

Hereinafter, exemplary embodiments of the present invention will be described in detail with reference the accompanying drawings. Like reference numerals are used to designate like or equivalent elements throughout this disclosure.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein the expression “and/or” includes any and all combinations of one or more of the associated listed items.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

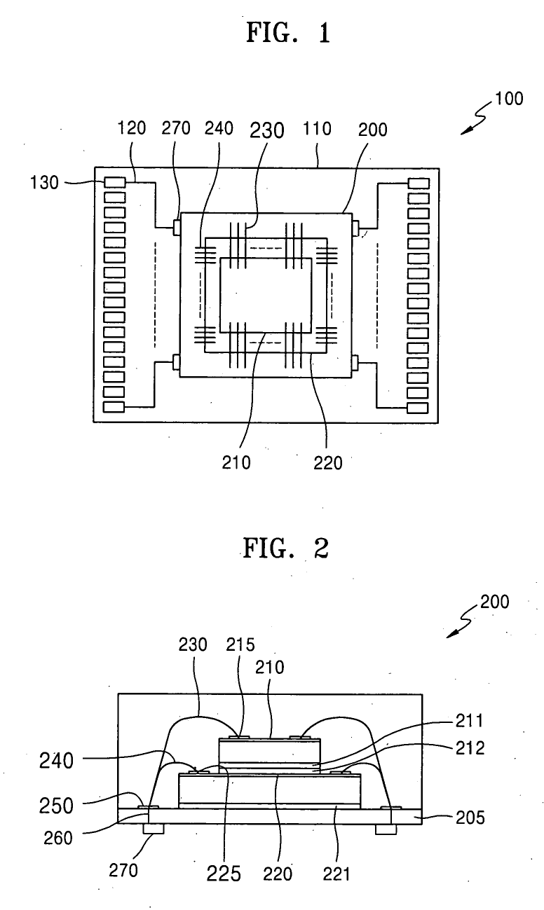

FIG. 1 is a view of a multi-chip package (MCP) mounted memory card 100 according to an embodiment of the present invention. The memory card 100 includes a MCP 200 in which a first memory chip 210 and a second memory chip 220 are installed. The memory chips 210, 220 may be any type of memory chip known to those skilled in this art, including, but not limiting to, flash memory, SRAM, SDRAM, and the like).

FIG. 2 illustrates the MCP 200 in detail. Referring to FIG. 2, the first chip 210 and the second chip 220 are deposited on a package board 205 of the MCP 200. The first chip 210 and the second chip 220 are in vertically stacked relationship. The second chip 220 may be affixed to the package board 205 via an adhesive tape layer 221. The first chip 210 may be affixed to the second chip 220 via an adhesive tape layer 211 and a layer adhesive layer 212. Those skilled in this art will appreciate that other techniques for affixing the chips to each other or to the package board may also be employed.

Electrode pads 215 on the first chip 210 are electrically connected to internal electrode terminals 250 in the package board 205 via wires 230, and electrode pads 225 on the second chip 220 are electrically connected to the internal electrode terminals via wires 240. In both cases the wires 230, 240 making electrical connections from the chips 210, 220 to the electrode terminals 250 on the package board extend over the periphery of the chip 210, 220 to the terminals 250. Each of the internal electrode terminals 250 is electrically connected to each of external electrode terminals 270 through a via hole 260 of the package board 205.

As illustrated in FIG. 1, each external electrode terminal 270 of the MCP 200 is connected to card connectors 130 via a conductive trace 120 on a printed circuit board (PCB) 110. The first and second chips 210 and 220 in the MCP 200 may be the same type of chip (e.g., both flash memory chips) or different from each other (e.g., flash memory and SRAM chips). The first and second chips 210 and 220 may be connected to input pins or output pins of the MCP 200 such that they are sharing the input pins or the output pins, or they may be separately connected to the input pins or the output pins of the MCP 200. Also, the first and second chips 210 and 220 may share a power supply line in the MCP 200 or have separate power supply lines.

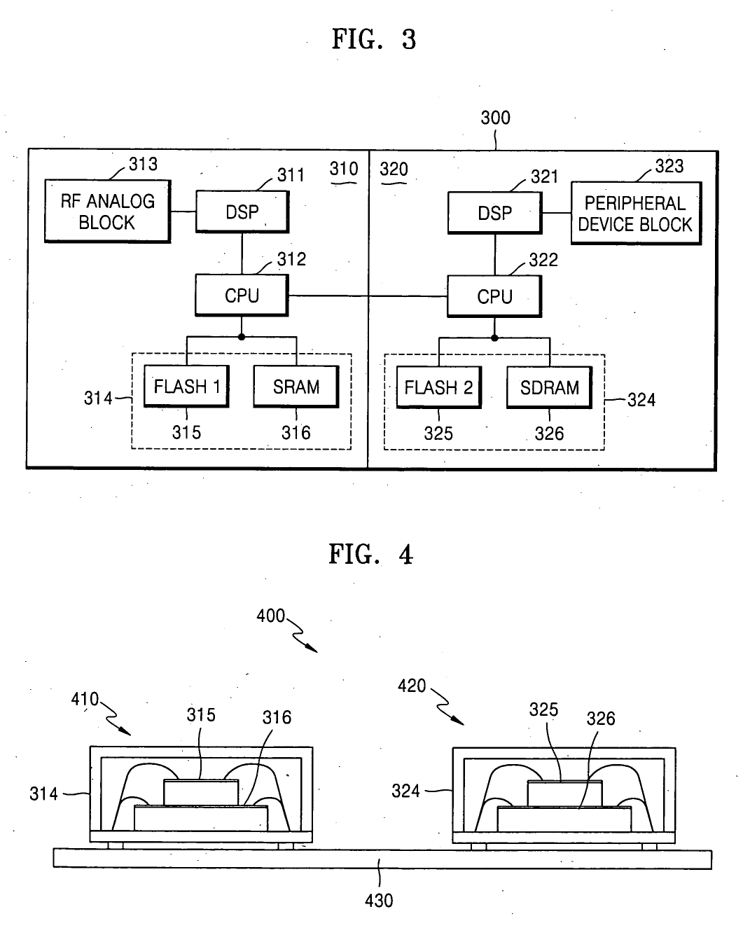

FIG. 3 is a block diagram of a communication and multimedia device 300 which is a mobile device with memory cards according to an embodiment of the present invention. The communication and multimedia device 300 includes a communication module 310 and a multimedia module 320.

The communication module 310 includes a digital signal processor (DSP) module 311, a central processing unit (CPU) module 312, a radio frequency (RF) analog module 313, and a first memory module 314. When an analog signal is input to the RF analog module 313, the analog signal is transmitted to the DSP module 311 and transformed into a digital signal by the DSP module 311. The CPU module 312 transmits communication signals processed by the DSP module 311 to the first memory module 314. A first flash memory 315 and an SRAM 316 are included in the first memory module 314 so that the first memory module 314 can store the communication signals transmitted via the CPU module 312. The first flash memory 315 may be a NOR flash memory, which stores codes for communication. The SRAM 316 executes the codes for communication stored in the first flash memory 315.

The multimedia module 320 includes a DSP module 321, a CPU module 322, a peripheral device module 323, and a second memory module 324. The DSP module 321 and the CPU module 322 process and control a signal that allows exchange of data among the DSP module 321, the CPU module 322, and the peripheral device module 323. A second flash memory 325 and an SDRAM 326 are included in the second memory module 324. The second flash memory 325 stores application codes of the peripheral device module 323, and the SDRAM 326 executes the application codes. The second flash memory 325 may be a NAND flash memory.

The first and second memory modules 314 and 324 of the communication and multimedia device 300 may be manufactured similarly to a memory card 400 illustrated in FIG. 4. Referring to FIG. 4, the memory card 400 is made by mounting a first MCP 410 and a second MCP 420 on a card PCB 430. As an example, a first flash memory 315 and an SRAM 316 of a first memory module 314 are deposited on the first MCP 410, and a second flash memory 325 and an SDRAM 326 of a second memory module 324 are deposited on the second MCP 420. The memory card 400 can be attached to and detached from the communication and multimedia device 300. In this manner, it is possible to easily increase the memory capacity and functions of the communication and multimedia device 300.

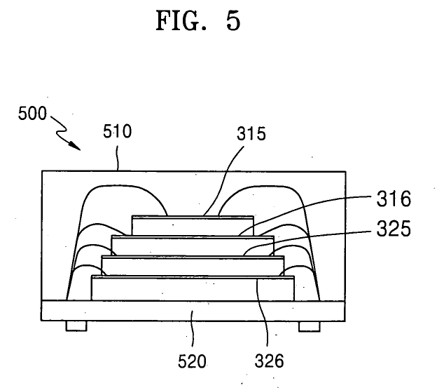

FIG. 5 is a cross-sectional view of a memory card 500 in which the first and second memory modules 314 and 324 of FIG. 3 are stacked on an MCP, according to an embodiment of the present invention. The memory card 500 is fabricated by mounting an MCP 510 on a card PCB 520. In the MCP 510, a first flash memory 315, an SRAM 316, a second flash memory 325, and an SDRAM 326 are deposited.

Those skilled in this art will recognize that the memory cards of the present invention may be suitable for use in a number of different environments, including mobile telephones, PDAs, other hand-held devices, and the like.

Although this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A memory card comprising:
a printed circuit board;
at least one multi-chip package mounted on the printed circuit board; and
card connectors electrically connected to electrode terminals of the multi-chip package via a conductive trace on the printed circuit board.

2. The memory card of claim 1, wherein different types of multi-chip packages are mounted.

3. The memory card of claim 1, wherein the same types of multi-chip packages are mounted.

4. The memory card of claim 1, wherein the same types of semiconductor chips are mounted on the at least one multi-chip package.

5. The memory card of claim 1, wherein different types of semiconductor chips are mounted on the at least one multi-chip package.

6. The memory card of claim 1, wherein input pins or output pins of the at least one multi-chip package are connected to the semiconductor chips in the at least one multi-chip package, such that the input pins or output pins are shared by the semiconductor chips.

7. The memory card of claim 1, wherein input pins or output pins of the at least one multi-chip package are separately connected to the semiconductor chips in the at least one multi-chip package.

8. The memory card of claim 1, wherein the semiconductor chips in the at least one multi-chip package comprise separate power supply lines.

9. The memory card of claim 1, wherein the semiconductor chips in the at least one multi-chip package share a power supply line.

10. A memory card, comprising:
a printed circuit board;
at least one multi-chip package mounted to the printed circuit board, the multi-chip package including a plurality of memory chips arranged in a vertically stacked relationship above a package board; and
card connectors mounted on the printed circuit board, the card connectors being electrically connected to electrode terminals of the package board of the multi-chip package.

11. The memory card of claim 10, wherein each of the memory chips is electrically connected to the electrode terminals of the package board via wires that extend over the periphery of the chip.

12. The memory card of claim 10, wherein the plurality of memory chips comprises at least two different kinds of memory chips.

13. The memory card of claim 10, wherein the at least one multi-chip package comprises two multi-chip packages.

14. The memory card of claim 13, wherein different types of multi-chip packages are mounted on the printed circuit board.

15. The memory card of claim 13, wherein the same types of multi-chip packages are mounted on the printed circuit board.

16. The memory card of claim 10, wherein input pins or output pins of the at least one multi-chip package are connected to the memory chips, such that the input pins or output pins are shared by the semiconductor chips.

17. The memory card of claim 10, wherein input pins or output pins of the at least one multi-chip package are separately connected to the memory chips in the at least one multi-chip package.

18. The memory card of claim 10, wherein the memory chips in the at least one multi-chip package comprise separate power supply lines.

19. The memory card of claim 1, wherein the memory chips in the at least one multi-chip package share a power supply line.

20. A memory card, comprising:
a printed circuit board; and
at least one multi-chip package mounted to the printed circuit board, the multi-chip package including a plurality of memory chips arranged in a vertically stacked relationship above a package board, wherein the plurality of memory chips comprise different kinds of memory chips.
